(19) United States
(12) Patent Application Publication
(10) Pub. No.: US 2010/0017157 A1
(43) Pub. Date: Jan. 21, 2010

(54) SYSTEM, METHOD AND APPARATUS FOR ACCURATE SIGNAL ANALYSIS

(75) Inventors: Madhusudhan Acharya, Karnataka (IN); Mukesh Soni, Bangalore (IN)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(73) Assignee: Tektronix, Inc., Beaverton, OR (US)

(21) Appl. No.: 12/481,513

(22) Filed: Jun. 9, 2009

(30) Foreign Application Priority Data
Jun. 10, 2008 (IN) 1235/MUM/2008

(51) Int. Cl. G01R 13/02; G06F 19/00

(52) U.S. Cl. 702/67

(57) ABSTRACT

The embodiments herein provide a device, method and a system to for accurate measurement and analysis of signals. The embodiments provided herein reduce distortions in the signal. The system is configured to center the eye by accurately measuring the skew (between the clock and data signal) and the jitter and then, compensating it from asymmetrical eye plot.

### FIELD OF THE INVENTION

The present invention relates generally to digital transmission systems and more particularly to measurement and analysis of signals.

### BACKGROUND OF THE INVENTION

Transmission systems form an important aspect of various telecommunication and industrial systems. The accurate transmission of information from one source to the other is increasingly desired. In designing such complex systems the engineers generally take help of various measurement and analysis tools to ensure the quality of the signal being transmitted. Also during normal running conditions of transmission system a check may need to be kept on the various interfering factors which may affect the signal quality.

One such analysis of the transmission system relies on plotting eye diagram of the signals and detailed analysis of same. The eye diagram gives visual information about the signal used in digital transmission and hence is useful in the evaluation and troubleshooting of digital transmission systems. From the eye diagram, digital systems designers can learn about the system performance and get insight into the nature of channel imperfections. Careful analysis of this visual display may give the user a first-order approximation of signal-to-noise, clock timing jitter and skew.

A typical eye diagram, as shown in FIG. 1, shows the variation of signal amplitude over the unit interval (one bit period) with multiple bits overlaid on each other. FIG. 2 explains the process of eye rendering by bit overlaying.

Typically the eye diagram includes two bit periods—The ‘eye’ is in the center (1-bit interval) with 2-half bit intervals on both the sides of the eye.

Electronic designers are interested in the measurement of certain parameters of the eye diagram for assessing the health of communication signal and system. Some of the measurements that are performed on a typical eye diagram are shown in FIG. 3.

However in measurement of the signal quality using eye diagram the skew between the data and clock signal or excessive jitter may result in eye diagram, which is not centered. In case of skewed eye diagram, the interval shown in the eye diagram can deviate from standard ‘half-one-half’ bit width as shown in FIG. 4.

The existing solutions address this problem by manually requesting user to enter a fixed anticipated (known) skew value and correct the eye diagram accordingly. However, the skew correction in such solution is fixed and does not account for the skew values dynamically varying over multiple acquisitions.

Also as the measurement analysis involves visual identification and analysis of the plot the accuracy of such analysis is greatly dependent on ability to rightly identify important points on the plot such as edges of the eye diagram plot.

There is therefore a need of a system which would allow a user or designer to accurately view the eye diagram accounting for any interferences, skew etc. which may generally affect the eye diagram plot.

### SUMMARY

A method and a system for accurate measurement and analysis of signals using eye diagram is described. The embodiments provided herein reduce distortions in the signal plot for better analysis. Further, the embodiments allow remodeling as per the requirement.

In one embodiment the system may be implemented in an oscilloscope. The oscilloscope in addition to the usual components may comprise of a plot identification module. The Plot identification module is configured to identify the start

The system and the method allows more accurate measurement and display of an eye diagram for better analysis. Also the chances of the error are reduced which may depend and vary from a user to user.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1 shows a typical Eye Diagram for Serial Data as per prior art.

FIG. 2 shows overlaying of individual bits (UI's) to form an Eye Diagram as per prior art.

FIG. 3 shows typical measurements on standard Eye Diagram as per prior art.

FIG. 4 shows an Eye diagram shifted to right due to data-clock skew and Jitter as per prior art.

FIG. 5 shows as per one embodiment a system for accurate display and analysis of an eye diagram plot of a communication.

FIG. 6 shows the Estimation of Eye diagram shift using data-clock skew and Jitter measurements.

FIG. 6 shows a flowchart describing the modification in the existing eye diagram rendering process for eye centering. The new process introduced is highlighted with color fill.

FIG. 7 shows as per an embodiment herein, the result as per an exemplary embodiment herein, wherein the clock and Data set-1 are processed.

FIG. 8 shows as per an embodiment herein, the result as per an exemplary embodiment herein, wherein the clock and Data set-1 are processed.

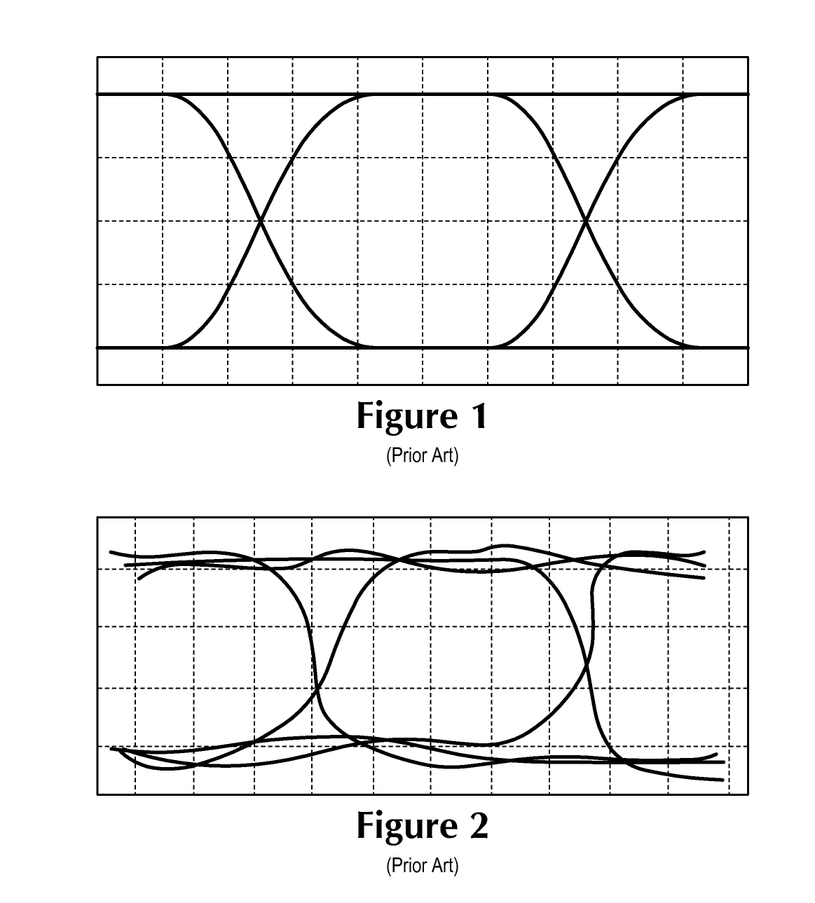

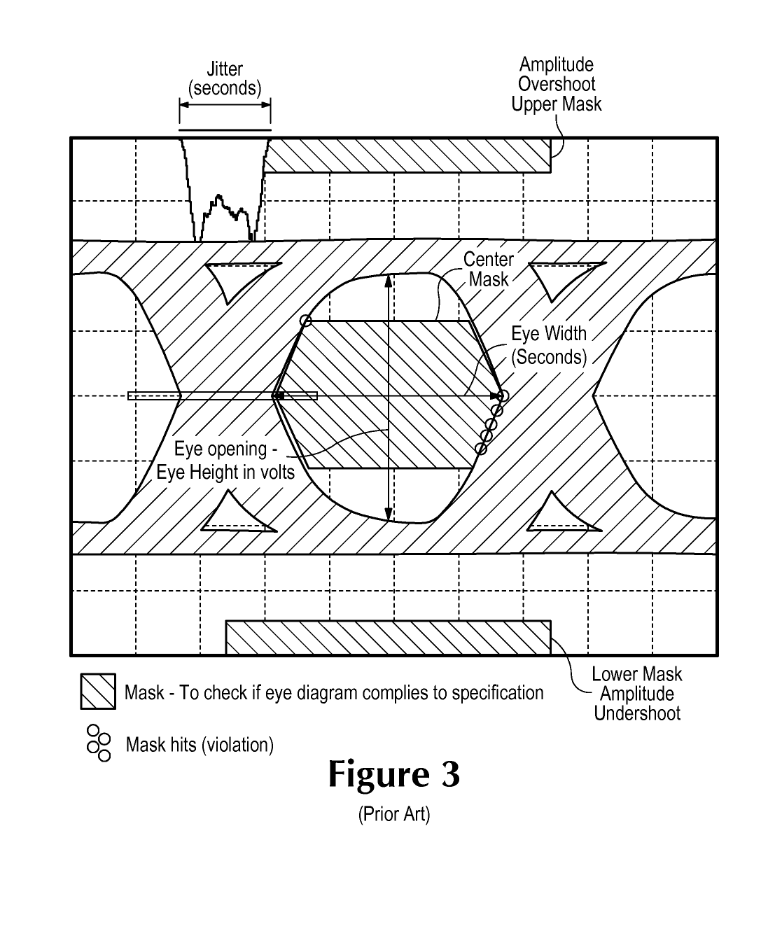

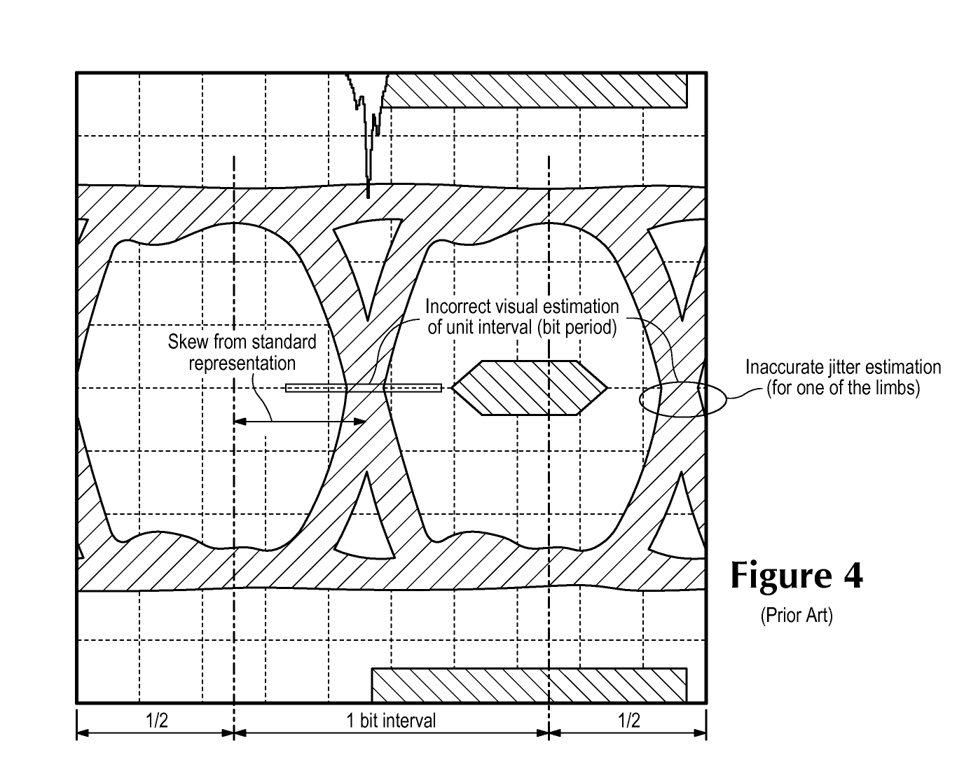

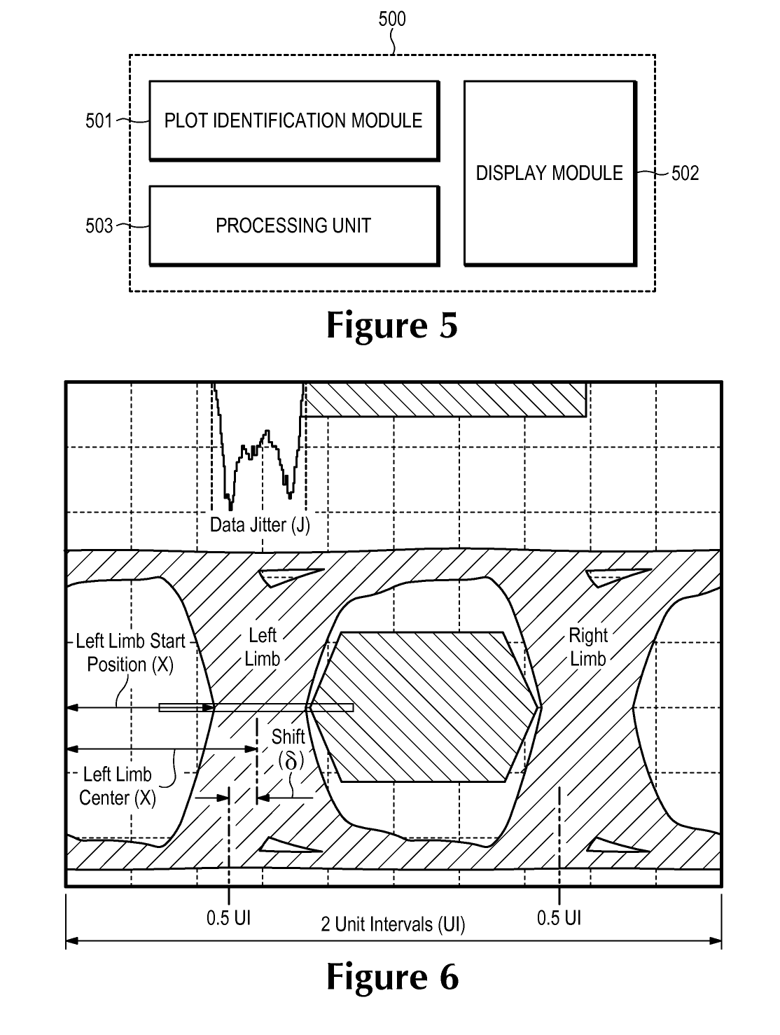

### DETAILED DESCRIPTION OF THE PREFERRED EMBODIMENTS

The embodiments herein provide a device, method and a system for accurate measurement and analysis of signals. The embodiments provided herein reduce distortions in the signal. Further, the embodiments allow remodeling as per the requirement. Further the embodiments may be easily implemented in various oscilloscopes. In one embodiment herein implementation in personal computer is made available.

The invention described herein is explained using specific exemplary details for better understanding. However, the invention disclosed can be worked on by a person skilled in the art without the use of these specific details. The invention can be implemented into a multiple types of digital storage oscilloscopes. Further, the invention may be implemented in hardware as well as software. Structures and devices shown in block diagram are illustrative of exemplary embodiments of the invention and are meant to avoid obscuring the invention. Also, the connections between various elements may not necessarily be direct and the data transfer in between can be subjected to encoding, re-formatting or modifications.

References in the specification to “one embodiment” or “an embodiment” means that a particular feature, structure, characteristic, or function described in connection with the embodiment is included in at least one embodiment of the invention. The appearances of the phrase “in one embodiment” in various places in the specification are not necessarily all referring to the same embodiment.

The system provided herein allows a user to accurately view the eye diagram of a transmission. The various interfering factors such as skew are accounted

The system is configured to center the eye by accurately measuring the skew (between the clock and data signal) and the jitter and then, compensating it from asymmetrical eye plot.

In one embodiment the system may be implemented in an oscilloscope. The oscilloscope in addition to the usual components may comprise of a plot identification module. The Plot identification module is configured to identify the start position of the various parts of the eye diagram which may be plotted on the display module. In one embodiment the identification of the left limb of the eye diagram is achieved.

A processing unit is configured to input information from the plot identification module and calculate the centre of the left limb of the eye. This calculation is carried out by using data jitter estimated using the histogram method and the position of the left limb. In such calculation, half the value of the jitter component is added to the position of the left limb to obtain the centre position of the left limb of the eye. The shift is calculated as =0.5*UI−Y. The shift may be applied to the plot and more accurate eye diagram may therefore be obtained. This is achieved by the said plot identification module, processing unit and the display module.

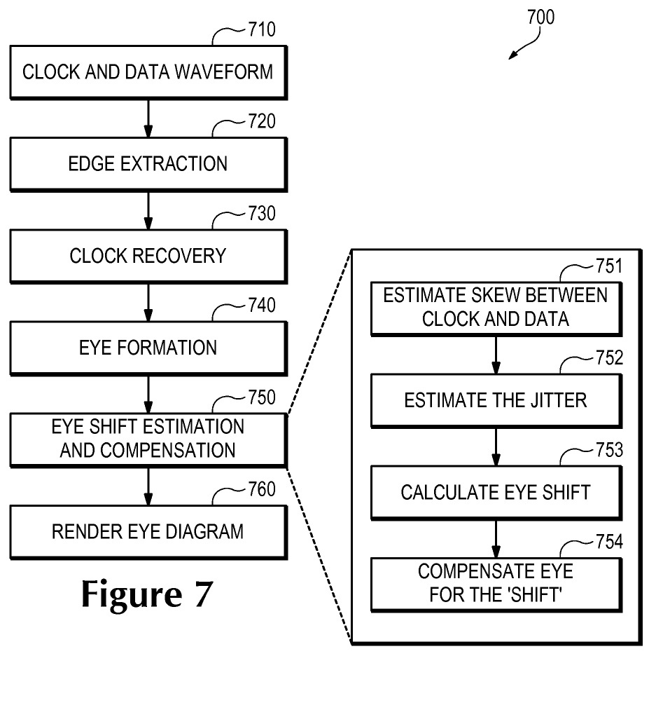

A method of measuring and plotting an accurate eye diagram is shown in FIG. 7 as per an embodiment herein, with reference to FIG. 6 showing estimation of eye diagram shift using data clock skew and jitter measurements. The method comprises the steps of receiving clock and data waveform and extracting the edge information of the asymmetric eye plot. Further the step involves recovery of clock information from the clock and data waveform.

Further, eye shift estimation and compensation takes place. This further comprises the calculations for enabling the method to be performed as described below. This involves the steps of:
Estimating data jitter after eye formation (but before rendering) using histogram method. (this jitter being called as “J”)
Finding the start position of the left limb of the eye diagram. Eye diagram has two limbs—left and right. (the left limb position is called “X”).
Calculating the center of left limb of the eye (Y) using data jitter (J) and left limb start position (X) by the formula:

Y=X+J/2.0
In case of ideal condition where there is no shift in the eye diagram, the center of the left limb should be at 50% of the unit interval (UI).
Calculating the shift ( ) as: =0.5*UI−Y where UI=Unit Interval (1 bit width)
Compensating the eye for this estimated shift and then eye diagram is rendered for the user analysis.

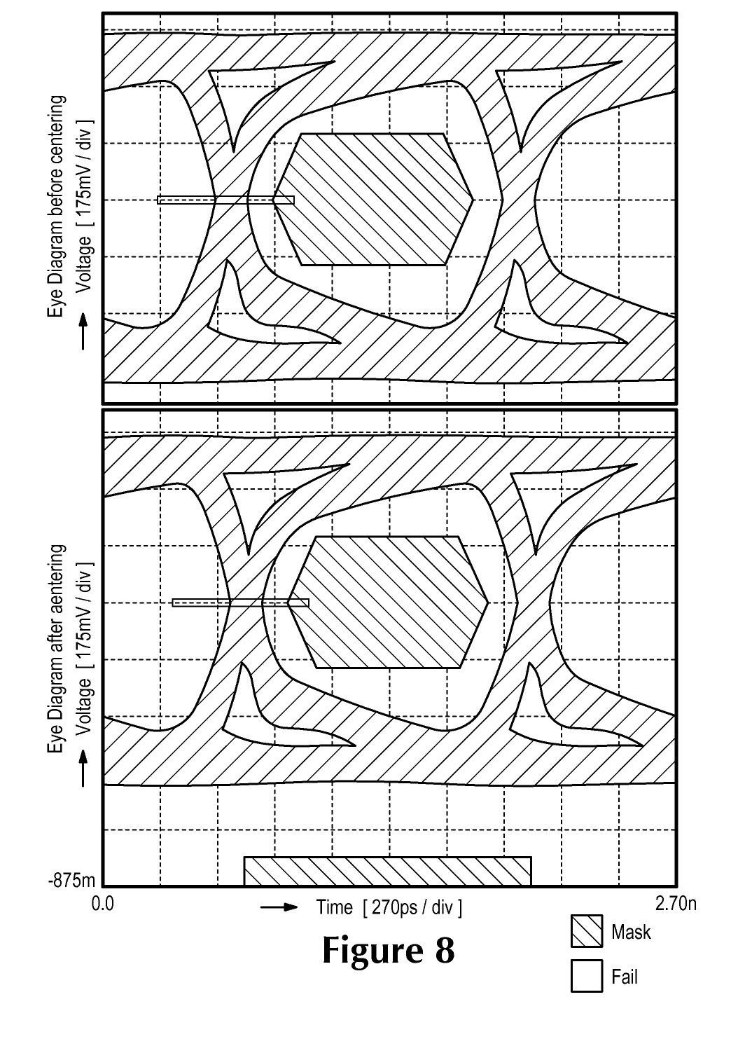

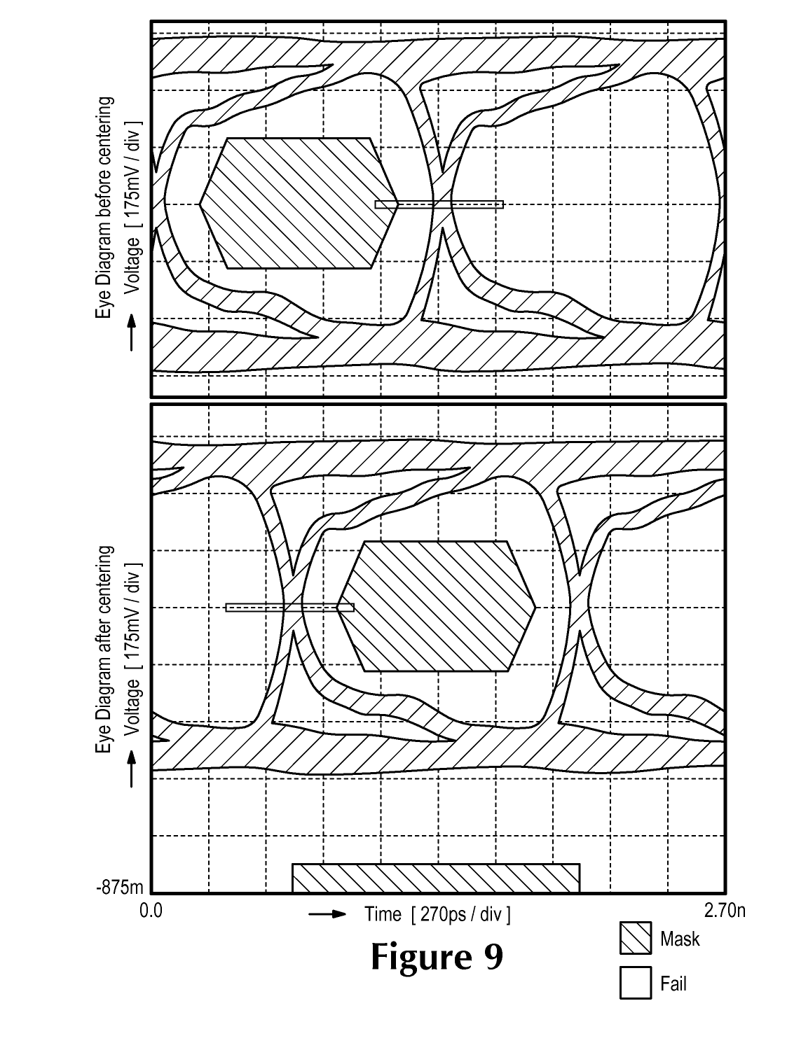

The method as described provides results as shown in FIG. 8. In FIG. 8 is shown as per an embodiment herein, the clock and Data set-1. The eye diagram shift is minimal (Shift≅0.05*UI). Further in FIG. 8 is shown a Clock and Data set-2. In this scenario the eye diagram shift is close to half of UI (Shift≅0.5*UI).

The system as provided herein would provide a simple and an accurate system for measuring and plotting eye diagram and carrying out further analysis from such plot. The accurate centering of the eye diagram by detecting the edges allows for a reliable centered eye plot. The system and method may easily be

The foregoing description of the invention has been described for purposes of clarity and understanding. It is not intended to limit the invention to the precise form disclosed.

We claim:

1. A method for accurate display and analysis of an eye diagram plot of a communication, the method comprising the steps of:
estimating data jitter using histogram method;
finding the start position of the left limb of the eye diagram;
calculating the center of left limb of the eye (Y) using data jitter (J) and left limb start position (X);
calculating estimated shift ( ) using Unit Interval and the centre of the left limb start position;
compensating the eye for the estimated shift.

2. The method as in claim one wherein, the calculation of the center of left limb of the eye (Y) using data jitter (J) and left limb start position (X) is performed by the formula:
Y=X+J/2.0

3. The method as in claim one wherein, the calculation of estimated shift ( ) is performed as:
=0.5*(Unit Interval)−(centre of the left limb start position).

4. A system for accurate display and analysis of an eye diagram plot of a communication comprising:
a plot identification module configured to identify the start position of the various parts of the eye diagram;
a processing unit configured to input information from the plot identification module, calculate the centre of the left part of the eye and utilize such information in calculating the shift required as correction in the eye diagram.
